(19) United States
(12) Patent Application Publication
(10) Pub. No.: US 2025/0261536 A1
(43) Pub. Date: Aug. 14, 2025

(54) DISPLAY DEVICE

(71) Applicant: Samsung Display Co., Ltd., Yongin-si (KR)

(72) Inventors: Tae Young SONG, Yongin-si (KR); Young Soo KWON, Yongin-si (KR); Yong Seok CHOI, Yongin-si (KR)

(73) Assignee: Samsung Display Co., Ltd., Yongin-si (KR)

(21) Appl. No.: 18/887,650

(22) Filed: Sep. 17, 2024

(30) Foreign Application Priority Data
Feb. 13, 2024 (KR) 10-2024-0020559

(51) Int. Cl. H10K 59/38; H10K 59/122; H10K 59/35; H10K 59/80

(52) U.S. Cl. CPC H10K 59/38; H10K 59/122; H10K 59/35; H10K 59/877; H10K 59/8792

(57) ABSTRACT

A display device includes a display layer and a light controlling layer. The light controlling layer is disposed on a surface of the display layer. The light controlling layer includes a color filter and a scattering layer. The color filter is disposed between the scattering layer and the display layer in a direction perpendicular to the surface of the display layer.

### CROSS-REFERENCE TO RELATED APPLICATION(S)

This U.S. non-provisional patent application claims priority to and the benefits of Korean Patent Application No. 10-2024-0020559 under 35 U.S.C. § 119, filed in the Korean Intellectual Property Office on Feb. 13, 2024, the entire contents of which are hereby incorporated by reference.

### BACKGROUND

### 1. Technical Field

The disclosure generally relates to a display device.

### 2. Description of the Related Art

In recent years, as interest in information display is increasing, research and development on display devices are continuously conducted.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

An aspect is capable of providing a display device with relatively high-resolution display quality by improving an aperture ratio corresponding to an area where light may be output.

An aspect is capable of providing a display device in which the risk of color mixing between sub-pixels may be reduced.

An aspect is capable of providing a display device with improved convenience in process design for manufacturing a pixel.

Additional aspects will be set forth in the detailed description, which follows, and in part, will be apparent from the disclosure, or may be learned by practice of the disclosed embodiments and/or the claimed subject matter.

According to some embodiments, a display device includes a display layer and a light controlling layer. The light controlling layer is disposed on a surface of the display layer. The light controlling layer includes a color filter and a scattering layer. The color filter is disposed between the scattering layer and the display layer in a direction perpendicular to the surface of the display layer.

In some embodiments, the display device may further include a first sub-pixel configured to emit light of a first color, a second sub-pixel configured to emit light of a second color, and a third sub-pixel configured to emit light of a third color. The scattering layer may respectively overlap each of the first sub-pixel, the second sub-pixel, and the third sub-pixel.

In some embodiments, the display device may further include a bank surrounding an area in a view in the direction. Each of the first sub-pixel, the second sub-pixel, and the third sub-pixel may form respectively sub-pixels of a pixel. The display device may include pixels and the pixel may one of the pixels. The color filter may include a first color filter overlapping the first sub-pixel in the direction, a second color filter overlapping the second sub-pixel in the direction, and a third color filter overlapping the third sub-pixel in the direction. The pixels may be spaced apart from one another by the bank. In a view in the direction, an outer boundary of the first color filter may correspond with an outer boundary of the first sub-pixel, an outer boundary of the second color filter may correspond with an outer boundary of the second sub-pixel, and an outer boundary of the third color filter may correspond with an outer boundary of the third sub-pixel.

In some embodiments, both the scattering layer and the color filter may directly contact a side surface of the bank.

In some embodiments, the scattering layer may include at least one of titanium oxide (TiOx), silica (SiOx), zirconium oxide (ZrOx), aluminum oxide (AlxOy), indium oxide (InxOy), zinc oxide (ZnOx), tin oxide (SnOx), and antimony oxide (SbxOy), where “x” and “y” are positive integers. The silica may optionally include at least one of silica beads and hollow silica. The display layer may include a light emitting element layer. The light emitting element layer may include a first light emitting element layer configured to emit light of the first color, a second light emitting element layer configured to emit light of the second color, and a third light emitting element layer configured to emit light of the third color.

In some embodiments, the display device may further include a filling layer disposed on the scattering layer, and an upper substrate disposed on the filling layer. The filling layer may be disposed between the upper substrate and the display layer in the direction.

In some embodiments, the display device may further include a filling layer disposed between the color filter and the display layer in the direction, and an upper substrate disposed on the scattering layer. The scattering layer may be disposed between the upper substrate and the display layer in the direction.

In some embodiments, the scattering layer may include at least one filing material and scatterers dispersed in the at least one filling material.

In some embodiments, the display device may further include a non-sub-pixel area that may not overlap any of the first sub-pixel, the second sub-pixel, and the third sub-pixel in the direction, and a black matrix layer. The bank and the black matrix layer may be disposed in the non-sub-pixel area.

In some embodiments, the display device may further include a low-reflection layer disposed on the upper substrate. The upper substrate may be disposed between the low-reflection layer and the display layer in the direction.

In some embodiments, the display device may further include a low-reflection layer disposed between the upper substrate and the filling layer in the direction.

In some embodiments, the display device may further include an optical layer overlapping each of the first sub-pixel, the second sub-pixel, and the third sub-pixel in the direction. A refractive index of the optical layer may be lower than a refractive index of the scattering layer.

In some embodiments, the display device may further include an intermediate bank structure disposed between at least two of the first sub-pixel, the second sub-pixel, and the third sub-pixel in a view in the direction. A height of the intermediate bank structure from the surface of the display layer in the direction may be smaller than a height of the bank from the surface of the display layer in the direction.

In some embodiments, the intermediate bank structure may include a first surface facing the display layer and a second surface opposing the first surface. The second surface of the intermediate bank structure may be covered by the color filter.

In some embodiments, the display device may further include a color conversion layer disposed between the first color filter and the display layer in the direction, and an intermediate bank surrounding at least a portion of the color conversion layer in a view in the direction.

In some embodiments, the display device may further include an optical layer disposed on the color filter. The optical layer may have a refractive index that is smaller than a refractive index of the scattering layer. A portion of the optical layer may be disposed between the first color filter and the color conversion layer in the direction and in an area overlapping the first sub-pixel in the direction.

In some embodiments, the display device may further include a first sub-pixel configured to emit light of a first color, a second sub-pixel configured to emit light of a second color, a third sub-pixel configured to emit light of a third color, and a color conversion layer overlapping the first sub-pixel in the direction. The color filter may include a first color filter overlapping the first sub-pixel in the direction, a second color filter overlapping the second sub-pixel in the direction, and a third color filter overlapping the third sub-pixel in the direction. The color conversion layer may be disposed between the first color filter and the display layer in the direction. The scattering layer may not overlap the first sub-pixel in the direction. The scattering layer may respectively overlap the second sub-pixel and the third sub-pixel in the direction.

In some embodiments, the display device may further include an intermediate bank structure disposed between the second sub-pixel and the third sub-pixel in a view in the direction. A height of the intermediate bank structure from the surface of the display layer in the direction may be smaller than a height of the bank from the surface of the display layer in the direction.

In some embodiments, the display device may further include an upper layer disposed on the light controlling layer. The upper layer may include a filling layer and an upper substrate disposed on the filling layer. The filling layer may be disposed between the upper substrate and the display layer in the direction. The first color filter may be disposed between the upper substrate and the filling layer in the direction.

In some embodiments, the display device may further include an optical layer. At least a first portion of the optical layer may be disposed on the color conversion layer. At least a second portion of the optical layer may be disposed on the scattering layer. A refractive index of the optical layer may be smaller than a refractive index of the scattering layer.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 is a plan view schematically illustrating a display device according to an embodiment.

FIG. 2 is a cross-sectional view schematically illustrating the display device of FIG. 1 according to an embodiment.

FIG. 3 is a diagram schematically illustrating a display layer according to an embodiment.

FIG. 4 is a schematic diagram for explaining a path of light provided by a light emitting element according to an embodiment.

FIGS. 5 to 7 are plan views schematically illustrating one or more display devices according to some embodiments.

FIGS. 8 to 17 are cross-sectional views schematically illustrating one or more display devices according to some embodiments.

FIGS. 18 to 20 are plan views schematically illustrating one or more display devices according to some embodiments.

FIGS. 21 to 27 are cross-sectional views schematically illustrating one or more display devices according to some embodiments.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, well-known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. When an embodiment may be implemented differently, a specific process order may be performed differently from the described order. For example, two consecutively described processes may be performed substantially at the same time or performed in an order opposite the described order. Also, like reference numerals and/or reference characters denote like elements.

When an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. When, however, an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items—it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the term “substantially,” if used herein, and unless otherwise specified, may mean within 5% of a referenced value. For example, substantially perpendicular may mean within ±5% of being parallel. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the particular illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, various embodiments will be described in detail with reference to the accompanying drawings.

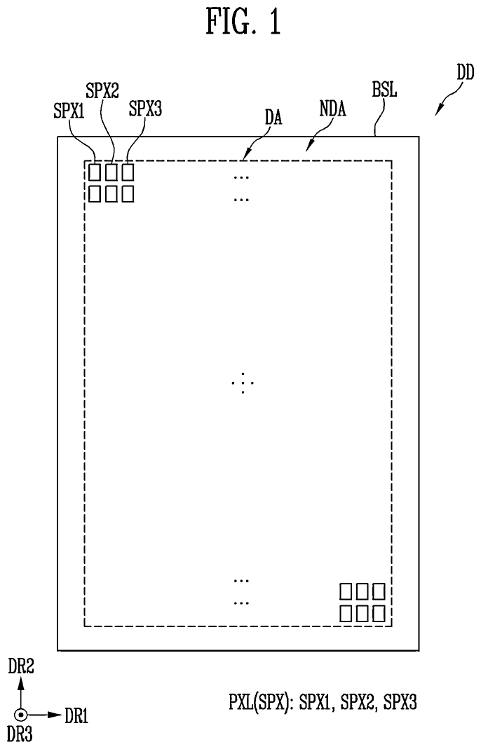

FIG. 1 is a plan view schematically illustrating a display device according to an embodiment.

Referring to FIG. 1, a display device DD may include a base layer BSL and a pixel PXL disposed on the base layer BSL. The display device DD may further include a driving circuit (for example, a scan driver and/or a data driver) for driving the pixel PXL, wirings, and pads.

The display device DD (or base layer BSL) may include a display area DA and a non-display area NDA. The non-display area NDA may refer to an area other than the display area DA. The non-display area NDA may surround at least a portion of the display area DA.

The base layer BSL may form a base surface of the display device DD. According to an embodiment, the base layer BSL may be a lower substrate on which one or more other layers forming the display device DD are disposed. The base layer BSL may be at least one of a rigid or flexible substrate or film. For example, the base layer BSL may include a glass material. In some implementations, the base layer BSL may include a silicon material. According to some embodiments, the base layer BSL may include polyimide. However, embodiments are not limited to the above-noted materials.

The display area DA may refer to an area where the pixel PXL is disposed. In some cases, the display area DA may refer to an area where an image may be displayed via the pixel PXL. The non-display area NDA may refer to an area where the pixel PXL is not disposed. In some instances, the non-display area NDA may refer to an area where an image is not displayed. The driving circuit, the wirings, and the pads electrically connected to the pixel PXL of the display area DA may be disposed in the non-display area NDA, but embodiments are not limited to such configurations.

According to an embodiment, the pixel PXL (or sub-pixels SPX) may be arranged according to an arrangement structure (or pattern), such as a stripe, PenTile™, or the like. However, embodiments are not limited to the aforementioned arrangement structures.

According to an embodiment, the pixel PXL (or sub-pixels SPX) may include a first sub-pixel SPX1, a second sub-pixel SPX2, and a third sub-pixel SPX3. The first sub-pixel SPX1, the second sub-pixel SPX2, and the third sub-pixel SPX3 may be sub-pixels. At least one first sub-pixel SPX1, at least one second sub-pixel SPX2, and at least one third sub-pixel SPX3 may form a unit pixel configured to emit light of various colors.

Each of the first sub-pixel SPX1, the second sub-pixel SPX2, and the third sub-pixel SPX3 may emit light of at least one color.

For example, the first sub-pixel SPX1 may be a red sub-pixel that emits red (for example, a first color) light. The second sub-pixel SPX2 may be a green pixel that emits green (for example, a second color) light. The third sub-pixel SPX3 may be a blue pixel that emits blue (for example, a third color) light. The red pixel may provide light in a wavelength range of approximately 600 nm to approximately 750 nm. The green pixel may provide light in a wavelength range of approximately 480 nm to approximately 560 nm. The blue pixel may provide light in a wavelength range of approximately 370 nm to approximately 460 nm.

According to an embodiment, the number of second sub-pixels SPX2 may be greater than the number of first sub-pixels SPX1 and the number of third sub-pixels SPX3. However, the color, type, and/or number of the first sub-pixel SPX1, the second sub-pixel SPX2, and the third sub-pixel SPX3 forming each unit pixel are not limited to the aforementioned examples.

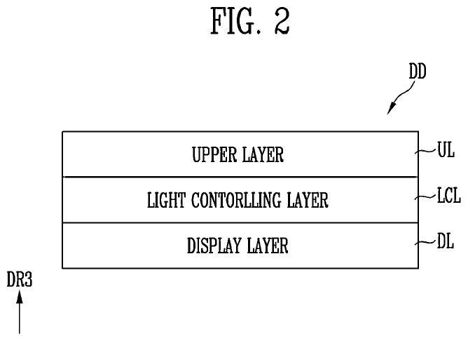

A more comprehensive structure, including a cross-sectional structure, of the display device DD described in association with FIG. 1 will be described in more detail with reference to FIGS. 2 to 4.

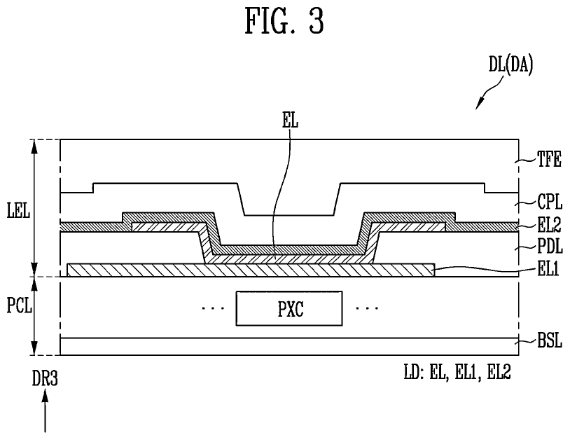

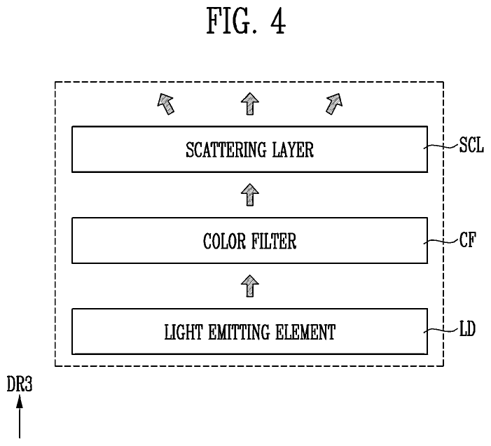

FIG. 2 is a cross-sectional view schematically illustrating the display device of FIG. 1 according to an embodiment. FIG. 3 is a diagram schematically illustrating a display layer according to an embodiment. FIG. 4 is a schematic diagram for explaining a path of light provided by (or emitted from) a light emitting element according to an embodiment.

Referring to FIGS. 2 to 4, the display device DD may include a display layer DL, a light controlling layer LCL, and an upper layer UL.

The display layer DL may be configured to emit light. The display layer DL may form a base on which the light controlling layer LCL is disposed.

The display layer DL may include a pixel circuit layer PCL including the base layer BSL and a light emitting element layer LEL including a light emitting element LD that form respective portions of the pixel PXL.

The base layer BSL may form a base on which a pixel circuit PXC is disposed. The pixel circuit PXC may be disposed on the base layer BSL and may be configured to drive the light emitting element LD. The pixel circuit layer PCL may include conductive layers and insulating layers, and the conductive layers may form the pixel circuit PXC. The pixel circuit PXC may include circuit elements configured to drive a sub-pixel SPX (or light emitting element LD of a sub-pixel SPX). The circuit elements may include a driving transistor and may further include one or more other transistors and capacitor(s).

The light emitting element layer LEL may be disposed on the pixel circuit layer PCL. According to an embodiment, the light emitting element layer LEL may include the light emitting element LD.

For example (see FIG. 3), the light emitting element LD may include (or be configured as) an organic light emitting diode (OLED), which may include at least one organic material. FIG. 3 schematically shows an embodiment in which the light emitting element LD is an organic light emitting diode. FIG. 3 shows a cross-sectional structure of the display device DD in the display area DA and schematically shows a cross-sectional structure of the display layer DL including the pixel circuit layer PCL and the light emitting element layer LEL.

According to an embodiment, the light emitting element layer LEL may further include a pixel defining layer PDL, a capping layer CPL, and an encapsulation layer TFE.

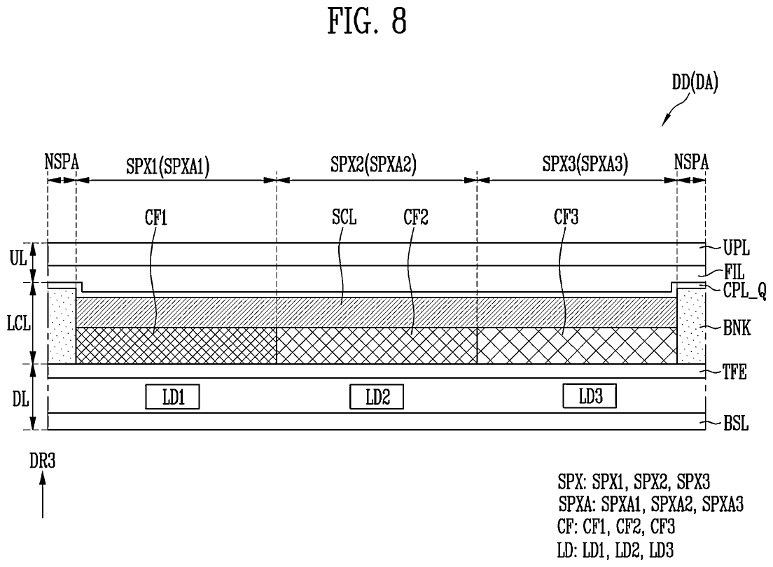

According to an embodiment, the light emitting element LD may be disposed on the pixel circuit layer PCL. The light emitting element LD may include a first light emitting element LD1 included in the first sub-pixel SPX1 (see FIG. 8), a second light emitting element LD2 included in the second sub-pixel SPX2 (see FIG. 8), and a third light emitting element LD3 included in the third sub-pixel SPX3 (see FIG. 8).

According to an embodiment, the light emitting element LD may include a first electrode EL1, a light emitting layer EL, and a second electrode EL2. According to an embodiment, the light emitting layer EL may be disposed in an area defined (or at least partially bounded) by the pixel defining layer PDL. For instance, the light emitting layer EL may be disposed in an opening formed in the pixel defining layer PDL. A side of the light emitting layer EL may be electrically connected to the first electrode EL1, and another side of the light emitting layer EL may be electrically connected to the second electrode EL2. In some embodiments, the side of the light emitting layer EL and the another side of the light emitting layer EL may oppose one another in a direction orthogonal to an upper surface of the base layer BSL, such as the third direction DR3.

The first electrode EL1 may be an anode electrode of the light emitting element LD, and the second electrode EL2 may be a cathode electrode of the light emitting element LD. It is contemplated, however, that the converse may also be true. For instance, the first electrode EL1 may be a cathode electrode of the light emitting element LD, and the second electrode EL2 may be an anode electrode of the light emitting element LD. According to an embodiment, the first electrode EL1 and the second electrode EL2 may include a conductive material. For example, the conductive material may include at least one of gold (Au), silver (Ag), aluminum (Al), molybdenum (Mo), chromium (Cr), titanium (Ti), nickel (Ni), neodymium (Nd), copper (Cu), and platinum (Pt). In some embodiments, the conductive material may additionally or alternatively include at least one of silver nanowire (AgNW), indium tin oxide (ITO), indium zinc oxide (IZO), indium gallium zinc oxide (IGZO), antimony zinc oxide (AZO), indium tin zinc oxide (ITZO), zinc oxide (ZnO), tin oxide (SnO₂), carbon nano tube, and graphene. However, embodiments are not limited to the above-noted materials.

The light emitting layer EL may emit light based on (or according to) an electrical signal provided from at least one of the anode electrode (for example, the first electrode EL1) and the cathode electrode (for example, the second electrode EL2). For instance, the light emitting layer EL may emit light based on (or according to) a potential difference across the anode electrode (for instance, the first electrode EL1) and the cathode electrode (for instance, the second electrode EL2).

The light emitting layer EL may include a multi-layer structure. For example, the light emitting layer EL may include multiple light emitting structures each of which may include a hole transport layer, a light emitting layer (or light generating layer), and an electron transport layer. Each layer forming a light emitting structure may include an organic material, and according to an embodiment, may further include an inorganic material, such as a metal-containing compound or quantum dots, or a combination thereof.

The hole transport layer may include a multi-layer structure having multiple layers each of which may include different materials or at least one of which may include a different material. As an example, the hole transport layer may include at least one of a hole injection layer and a hole transport layer, and according to an embodiment, may further include at least one of a light emitting auxiliary layer, an electron blocking layer, and the like. For example, the hole transport layer may have a multi-layer structure, such as a hole injection layer/a hole transport layer, a hole injection layer/a hole transport layer/a light emitting auxiliary layer, a hole injection layer/a light emitting auxiliary layer, a hole transport layer/a light emitting auxiliary layer, an electron blocking layer/a hole injection layer/a hole transport layer, hole transport layers arranged sequentially and including different materials, a hole injection layer/a hole transport layer/an electron blocking layer, or the like. However, embodiments are not limited to the above-noted structures.

The light emitting layer may include a material configured to emitting light of at least one color. The light emitting layer may include a host and a dopant. The host of the light emitting layer may be a light emitting material that is configured to capture carriers (e.g., electrons and holes) for generating light and may induce relatively efficient generation of excitons. The dopant may include a phosphorescent dopant or a fluorescent dopant, or a combination thereof. The dopant, however, is not limited to the aforementioned examples. According to an embodiment, the dopant may additionally or alternatively include an organic material and may additionally or alternatively include a metal complex and/or the like.

The electron transport layer may include a multi-layer structure having multiple layers each of which may include different materials or at least one of which may include a different material. The electron transport layer may include at least one of an electron injection layer and an electron transport layer, and according to an embodiment, may further include at least one of an electron buffer layer, a hole blocking layer, and the like. For example, the electron transport layer may have a multi-layer structure, such as an electron transport layer/an electron injection layer, a hole blocking layer/an electron transport layer/an electron injection layer, an electron control layer/an electron transport layer/an electron injection layer, a buffer layer/an electron transport layer/an electron injection layer, or the like. However, embodiments are not limited to the above-noted structures.

The pixel defining layer PDL may be disposed on the pixel circuit layer PCL to define (or at least partially bound) a position where the light emitting layer EL is arranged. The pixel defining layer PDL may include an organic material. For example, the pixel defining layer PDL may include at least one of an acrylic resin, an epoxy resin, a phenol resin, a polyamide resin, and a polyimide resin. However, embodiments are not limited to the aforementioned materials. In some embodiments, the pixel defining layer PDL may include an inorganic material. For example, the pixel defining layer PDL may include at least one of silicon oxide (SiOx) and silicon nitride (SiNx), where “x” is a positive integer. According to an embodiment, the pixel defining layer PDL may have a multi-layer structure in which a layer including silicon oxide (SiOx) and a layer including silicon nitride (SiNx) are stacked on each other.

The capping layer CPL may be disposed on the second electrode EL2. The capping layer CPL may cap or cover the second electrode EL2. The capping layer CPL may include an inorganic material.

The encapsulation layer TFE may be disposed on the light emitting element LD (for example, the second electrode EL2). The encapsulation layer TFE may reduce a step difference caused, at least in part, by an underlying formation of the light emitting element LD and the pixel defining layer PDL. The encapsulation layer TFE may include multiple insulating layers covering the light emitting element LD. According to an embodiment, the encapsulation layer TFE may have a structure in which one or more inorganic layers and one or more organic layers are alternately stacked on each other. According to an embodiment, the encapsulation layer TFE may be a thin film encapsulation layer.

The light controlling layer LCL may be disposed on the display layer DL (for example, the light emitting element layer LEL). For example, the light controlling layer LCL may be disposed on a first (e.g., an upper) side of the display layer DL based on a display direction (for example, a third direction DR3).

According to an embodiment, the light controlling layer LCL may include a layer that is configured to change the color of incident light and may include a layer that scatters incident light. For example, the light controlling layer LCL may include a color filter CF and a scattering layer SCL. The color filter CF may selectively transmit light of a color. The scattering layer SCL may scatter incident light. In some cases, the light controlling layer LCL may be configured to change the color of incident light and/or scatter incident light as the incident light propagates through the light controlling layer LCL.

The color filter CF may be disposed between the light emitting element LD and the scattering layer SCL. For example, the light emitting element LD, the color filter CF, and the scattering layer SCL may be arranged in order based on the third direction DR3.

The upper layer UL may be disposed on the light controlling layer LCL. For example, the upper layer UL may be disposed on a first (e.g., an upper) side of the light controlling layer LCL based on the display direction (for example, the third direction DR3).

According to an embodiment, the upper layer UL may include an upper substrate UPL (see FIG. 8). According to an embodiment, the upper layer UL may include various structures and/or layers to improve the display quality of the display device DD.

Referring to FIG. 4, according to an embodiment, structural features of the display device DD, which are designed to realize relatively high-resolution display quality and reduce the risk of color mixing between the sub-pixels SPX, will be described.

According to an embodiment, light provided by (or emitted from) the light emitting element LD may be provided (for example, output) in the display direction (for example, the third direction DR3). The color filter CF may be disposed on the light emitting element LD along the third direction DR3, and the scattering layer SCL may be disposed on the color filter CF. Accordingly, the light provided by the light emitting element LD may sequentially pass through the color filter CF and the scattering layer SCL.

According to an embodiment, as the light provided by the light emitting element LD sequentially passes through the color filter CF and the scattering layer SCL, viewing angle characteristics of the display device DD may be improved.

For example, the scattering layer SCL may be generally disposed at the periphery of the display device DD based on the display direction, e.g., the third direction DR3. Accordingly, light generated by the sub-pixel SPX may be relatively efficiently scattered, thereby improving the viewing angle characteristics of the display device DD.

According to an embodiment, the scattering layer SCL may be disposed on the color filter CF and may be formed across two or more sub-pixels SPX, such as two or more sub-pixels SPX adjacent (e.g., directly adjacent) to one another. Accordingly, the viewing angle characteristics of the display device DD may be further improved.

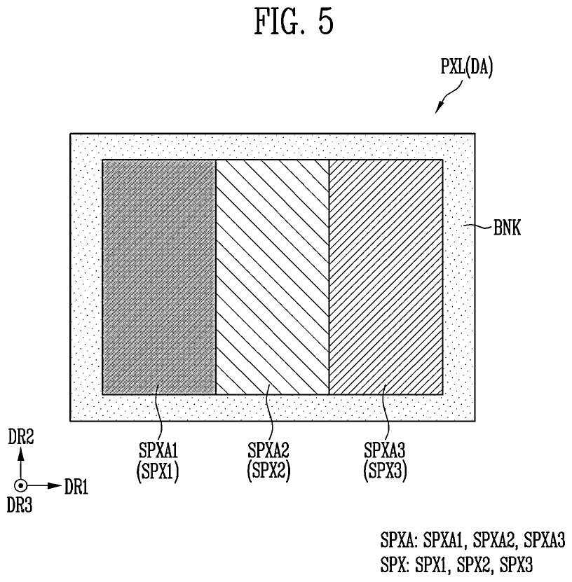

According to an embodiment, at least because the scattering layer SCL is disposed above the color filter CF, the risk of color mixing between the sub-pixels SPX can be reduced. This will be described in more detail below with reference to one or more of the drawings after FIG. 5.

According to an embodiment, at least because the scattering layer SCL is disposed above the color filter CF, the risk of excessive formation (e.g., thickness in the third direction DR3) of a bank structure in the pixel PXL can be reduced. At least because the bank structure is not excessively formed in the pixel PXL, light loss due to the bank structure can be reduced. Therefore, light output efficiency of the display device DD may be improved. This will be described in more detail below with reference to one or more the drawings after FIG. 5.

One or more display devices according to various embodiments will now be described with reference to FIGS. 5 to 17. Content that overlaps with the above-described content will be briefly explained or omitted.

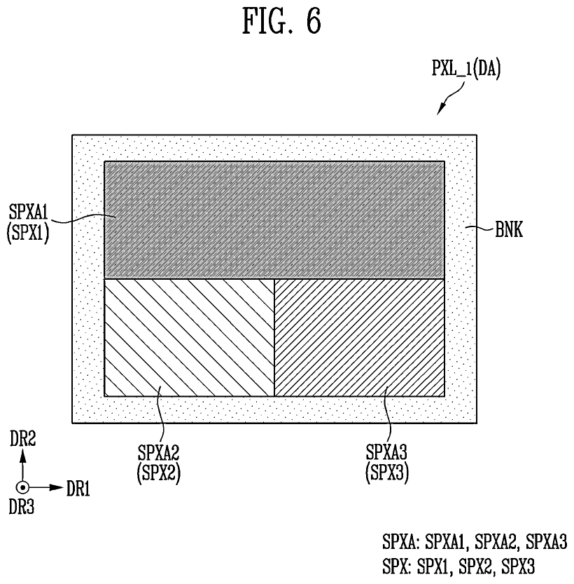

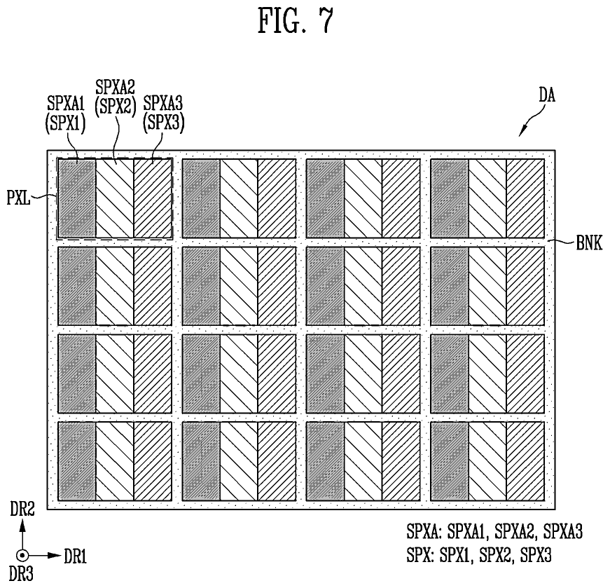

FIGS. 5 to 7 are plan views schematically illustrating one or more display devices according to some embodiments. As used, herein, a “plan view” may be a view of a display device in a direction perpendicular to a first (e.g., upper) surface of the base layer BSL. For instance, a “plan view” may be a view in a case that a display device is viewed in the third direction DR3. FIGS. 5 and 6 schematically show respective pixels PXL and PXL_1, and in particular, schematically show various arrangement structures of different sub-pixels SPX. FIG. 7 schematically shows an arrangement structure in which pixels PXL are sequentially arranged.

FIGS. 8 to 17 are cross-sectional views schematically illustrating one or more display devices according to some embodiments. For instance, FIGS. 8 to 17 schematically show cross-sectional views of the first to third sub-pixels SPX1 to SPX3 according to some embodiments.

Referring to FIGS. 5 to 7, a display device may include a bank BNK disposed in the display area DA. The pixel PXL (or PXL_1) may include one or more sub-pixels SPX, and the pixels PXL (or PXL_1) and/or sub-pixels SPX may be arranged according to any suitable arrangement structure or pattern. For example, the pixels PXL may be arranged in a matrix structure based on a first direction DR1 and a second direction DR2, which may be transverse to the first direction DR1. However, embodiments are not limited to the aforementioned arrangement structures.

According to an embodiment, the sub-pixels SPX may be arranged in various structures. For example (see FIG. 5), the first to third sub-pixels SPX1 to SPX3 may be sequentially arranged along a direction (for example, the first direction DR1). In some embodiments (see FIG. 6), the second and third sub-pixels SPX2 and SPX3 may be arranged along the first direction DR1, and the first sub-pixel SPX1 may be arranged adjacent to the second and third sub-pixels SPX2 and SPX3 along the second direction DR2 different from (for example, perpendicular to) the first direction DR1. However, embodiments are not limited to the above-noted arrangements.

The pixels PXL (or PXL_1) may be distinguished from each other based on the bank BNK. For example, the bank BNK may be disposed between the pixels PXL (or PXL_1) that are adjacent to each other. According to an embodiment, the bank BNK may be adjacent (e.g., directly adjacent) to the pixel PXL (or PXL_1) in one or more directions. The bank BNK may surround each of the pixels PXL (or PXL_1) in a plan view.

Each of the pixels PXL may include the sub-pixels SPX. The sub-pixels SPX may form (or may be disposed in) respective sub-pixel areas SPXA. Each of the sub-pixel areas SPXA may be an area where light of a color is emitted.

The sub-pixel areas SPXA may include a first sub-pixel area SPXA1 where the first sub-pixel SPX1 is formed and light of the first color is provided, a second sub-pixel area SPXA2 where the second sub-pixel SPX2 is formed and light of the second color is provided, and a third sub-pixel area SPXA3 where the third sub-pixel SPX3 is formed and light of the third color is provided.

According to an embodiment, the bank BNK may be adjacent (e.g., directly adjacent) to the sub-pixel areas SPXA. For example, the bank BNK may be adjacent (e.g., directly adjacent) to the first sub-pixel area SPXA1 in a plan view. The bank BNK may be adjacent (e.g., directly adjacent) to the second sub-pixel area SPXA2 in a plan view. The bank BNK may be adjacent (e.g., directly adjacent) to the third sub-pixel area SPXA3 in a plan view.

According to an embodiment, sub-pixel areas SPXA of different colors may be adjacent (e.g., directly adjacent) to each other in a plan view. For example, the first and second sub-pixel areas SPXA1 and SPXA2 may be adjacent (e.g., directly adjacent) to each other in a plan view. The first and third sub-pixel areas SPXA1 and SPXA3 may be adjacent (e.g., directly adjacent) to each other in a plan view. The second and third sub-pixel areas SPXA2 and SPXA3 may be adjacent (e.g., directly adjacent) to each other in a plan view.

According to an embodiment, the bank BNK may not be disposed between sub-pixel areas SPXA in a pixel PXL (or pixel PXL_1). Accordingly, a range in which the bank BNK is formed in an area where the pixel PXL or PXL_1 is formed can be minimized or at least reduced relative to a conventional display device. Hereinafter, it will be assumed that the pixel arrangement is as shown in FIG. 5. As such, the pixel(s) will be referred to as pixel PXL or pixels PXL. It is noted, however, that the effects and/or advantages described in association with pixels PXL are also applicable to other pixel arrangements, such as the pixel arrangement described in association with pixel PXL_1.

In this specification, the bank BNK may be a structure that surrounds an area and protrudes in a thickness direction of the base layer BSL (for example, the third direction DR3).

In a case that the bank BNK is disposed in an area where the pixel PXL is formed, light provided by the light emitting element LD may be absorbed by the bank BNK, resulting in light loss.

As the range in which the bank BNK is formed in the area where the pixel PXL is formed is minimized (or at least reduced), an aperture ratio formed by the bank BNK can be improved. Accordingly, a range (or area) in which the sub-pixel areas SPXA are formed can be increased.

However, according to an embodiment, the bank BNK may not be disposed in the area where the pixel PXL is formed, and the above-mentioned risks may be reduced. Accordingly, the display device DD with improved light output efficiency can be provided.

As the range in which the bank BNK is formed in the area where the pixel PXL is formed is minimized (or at least reduced), design freedom of the sub-pixels SPX can be improved, and manufacturing process convenience can be improved.

FIGS. 8 to 17 show a cross-sectional structure of one or more display devices in the display area DA according to some embodiments. For convenience of description, a cross-sectional structure in which the first to third sub-pixels SPX1 to SPX3 are sequentially arranged are shown.

According to an embodiment, the display device DD may include light emitting elements LD that provide different colors in association with each sub-pixel SPX among the first sub-pixel SPX1, the second sub-pixel SPX2, and the third sub-pixel SPX3.

Referring to FIG. 8, in the display layer DL, the light emitting element LD may include the first to third light emitting elements LD1 to LD3 disposed on the base layer BSL.

According to an embodiment, the first light emitting element LD1 may be disposed in the first sub-pixel area SPXA1 and may provide light of the first color. For example, the first light emitting element LD1 may be a red light emitting element. The second light emitting element LD2 may be disposed in the second sub-pixel area SPXA2 and may provide light of the second color. For example, the second light emitting element LD2 may be a green light emitting element.

The third light emitting element LD3 may be disposed in the third sub-pixel area SPXA3 and may provide light of the third color. For example, the third light emitting element LD3 may be a red light emitting element.

The light controlling layer LCL may be disposed on the display layer DL (for example, the encapsulation layer TFE). The light controlling layer LCL may include the bank BNK, the color filter CF, the scattering layer SCL, and an upper capping layer CPL_Q.

The bank BNK may be disposed on the display layer DL (for example, the encapsulation layer TFE). The bank BNK may protrude in the thickness direction of the base layer BSL (for example, in the third direction DR3) and may surround the sub-pixel areas SPXA. For example, the bank BNK may surround the color filters CF. The bank BNK may surround the scattering layer SCL. For example, an upper surface of the bank BNK may be further spaced apart from the base layer BSL in, for example, the third direction DR3 than the color filters CF and the scattering layer SCL.

The bank BNK may overlap a non-sub-pixel area NSPA in a plan view. For instance, the bank BNK may overlap a non-sub-pixel area NSPA in a direction perpendicular to an upper surface of base layer BSL. The bank BNK may not overlap the sub-pixel area SPXA in a plan view, e.g., in the direction perpendicular to the upper surface of the base layer BSL. A side surface of the bank BNK may be adjacent (e.g., directly adjacent) to (for example, in contact with) one or more of the color filters CF and the scattering layer SCL. According to an embodiment, the non-sub-pixel area NSPA may be an area other than the sub-pixel area SPXA, and may be an area where light is not visually recognized.

The bank BNK may include various materials. For example, the bank BNK may include an organic material. According to an embodiment, the bank BNK may include at least one of an acrylic resin, an epoxy resin, a phenol resin, a polyamide resin, and a polyimide resin. According to an embodiment, the bank BNK may include a light blocking material (for example, a black matrix material). However, embodiments are not limited to the aforementioned materials.

The color filters CF may be disposed on the display layer DL (for example, the encapsulation layer TFE). The color filters CF may be disposed in an area surrounded by the bank BNK in a view in the third direction DR3. According to an embodiment, the color filters CF may be formed using at least one photolithography process, but any additional or alternative process(es) may be utilized.

According to an embodiment, the color filters CF may define the sub-pixel areas SPXA. In some implementations, an outer boundary of the color filters CF may correspond with an outer boundary of the sub-pixel areas SPXA. For example, an area where a first color filter CF1 is disposed may correspond to (for example, may be substantially the same as) the first sub-pixel area SPXA1 in a plan view. An area where a second color filter CF2 is disposed may correspond to (for example, may be substantially the same as) the second sub-pixel area SPXA2 in a plan view. An area where a third color filter CF3 is disposed may correspond to (for example, may be substantially the same as) the third sub-pixel area SPXA3 in a plan view.

According to an embodiment, the color filters CF may be disposed between the display layer DL (e.g., the encapsulation layer TFE of the display layer DL) and the scattering layer SCL.

The color filters CF may include first to third color filters CF1 to CF3 corresponding to the sub-pixels SPX. For example, the color filters CF may include the first color filter CF1, the second color filter CF2, and the third color filter CF3.

The first color filter CF1 may be disposed in the first sub-pixel area SPXA1. The first color filter CF1 may include a color filter material (for example, dye or pigment, or a combination thereof) that selectively transmits light of the first color (for example, a red color).

The second color filter CF2 may be disposed in the second sub-pixel area SPXA2. The second color filter CF2 may include a color filter material (for example, dye or pigment, or a combination thereof) that selectively transmits light of the second color (for example, a green color).

The third color filter CF3 may be disposed in the third sub-pixel area SPXA3. The third color filter CF3 may include a color filter material (for example, dye or pigment, or a combination thereof) that selectively transmits light of the third color (for example, a blue color).

The scattering layer SCL may be disposed on the color filters CF. The scattering layer SCL may be disposed in an area surrounded by the bank BNK. According to an embodiment, the scattering layer SCL may be adjacent (e.g., directly adjacent) to the color filters CF. For example, the scattering layer SCL may be disposed on, e.g., disposed directly on, the color filters CF. However, embodiments are not limited to the aforementioned arrangements.

The scattering layer SCL may include scatterers and a matrix material (for example, an organic material) in which the scatterers are dispersed. Accordingly, light incident from the color filters CF may be scattered in the scattering layer SCL and emitted to the outside of the display device DD. According to an embodiment, the scattering layer SCL may include at least one of titanium oxide (TiOx), silica (SiOx) (for example, silica beads, hollow silica, or the like), zirconium oxide (ZrOx), aluminum oxide (AlxOy), indium oxide (InxOy), zinc oxide (ZnOx), tin oxide (SnOx), and antimony oxide (SbxOy), where “x” and “y” are positive integers. However, embodiments are not limited to the above-noted materials.

According to an embodiment, at least some of the sub-pixels SPX may share a same scattering layer SCL with one another. For example, the scattering layer SCL may be disposed across the sub-pixel areas SPXA of a pixel PXL. The scattering layer SCL may be disposed across the first sub-pixel area SPXA1, the second sub-pixel area SPXA2, and the third sub-pixel area SPXA3. According to an embodiment, the scattering layer SCL may include a first portion included in the first sub-pixel SPX1, a second portion included in the second sub-pixel SPX2, and a third portion included in the third sub-pixel SPX3. The first to third portions may be formed integrally with each other. For instance, the first to third portions of the scattering layer SCL may be integral with each other, e.g., the first to third portions of the scattering layer SCL may be contiguous with each other and/or may be portions of a single body.

According to an embodiment, at least because the scattering layer SCL disposed on the color filter CF is disposed across the sub-pixels SPX, manufacturing process convenience can be improved and the viewing angle characteristics of the display device DD can be also be improved.

According to an embodiment, at least because the scattering layer SCL disposed on the color filter CF is disposed across the sub-pixels SPX, the risk of color mixing between the sub-pixels SPX can be also be reduced.

In a case that the scattering layer SCL is disposed below the color filters CF, at least a portion of light scattered by the scattering layer SCL formed in a sub-pixel SPX may be incident to at least one of the other sub-pixels SPX, and the light may be applied to a corresponding one of the color filters CF corresponding to the at least one of the other sub-pixels SPX. This may cause, at least in part, a risk that light of intended light information (for example, light of an intended color and luminance) is not provided from the at least one of the other sub-pixels SPX.

In a case that the scattering layer SCL is disposed below the color filters CF, and quantum dots that change the color of light of a color are disposed in the scattering layer SCL and light propagates unnecessarily between adjacent sub-pixels SPX, there may be a risk that light of unintended color and/or luminance is generated from an unintended sub-pixel SPX.

However, according to an embodiment, at least because the scattering layer SCL disposed on the color filter CF may be disposed across the sub-pixels SPX, the above-mentioned risk can be reduced. Accordingly, the display device DD with relatively excellent display quality can be provided by preventing (or at least mitigating) light loss and reducing the risk of color mixing. The possibility of the above-mentioned risk occurring may increase as the resolution of the display device DD increases, but according to some embodiments, the display device DD can be manufactured to have relatively high resolution and relatively excellent display quality at least because the above-mentioned risk can be mitigated through the relative disposition and configuration of the color filters CF and the scattering layer SCL.

The upper capping layer CPL_Q may be disposed on both the bank BNK and the scattering layer SCL. The upper capping layer CPL_Q may protect both the bank BNK and the scattering layer SCL. The upper capping layer CPL_Q may be physically separated from the color filters CF via at least the scattering layer SCL.

The upper capping layer CPL_Q may be an inorganic layer. The upper capping layer CPL_Q may include at least one of silicon nitride (SiNx), aluminum nitride (AlNx), titanium nitride (TiNx), silicon oxide (SiOx), aluminum oxide (AlxOy), titanium oxide (TiOx), silicon oxycarbide (SiOxCy), and silicon oxynitride (SiOxNy), where “x” and “y” are positive integers. However, embodiments are not limited to the above-noted materials.

The upper layer UL may be disposed on the light controlling layer LCL. According to an embodiment, the upper layer UL may include a filling layer FIL and the upper substrate UPL.

According to an embodiment, the light controlling layer LCL may be disposed on the display layer DL, and the upper substrate UPL may be provided on the light controlling layer LCL. The display device DD, according to an embodiment, may be manufactured by disposing the filling layer FIL between the light controlling layer LCL and the upper substrate UPL.

The filling layer FIL may be disposed between the light controlling layer LCL and the upper substrate UPL. The filling layer FIL may include various transparent organic materials (for example, an acrylic resin), but the material of the filling layer FIL is not limited to the aforementioned examples.

The upper substrate UPL may be a transparent substrate. For example, the upper substrate UPL may include glass. However, embodiments are not limited to the upper substrate UPL including glass. According to an embodiment, the upper substrate UPL may include various materials. According to an embodiment, the upper layer UL may include various functional film layers other than the upper substrate UPL.

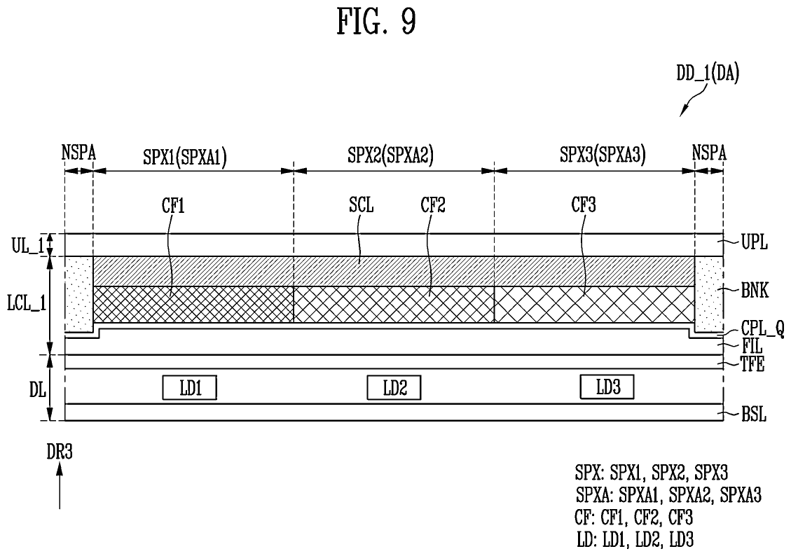

Referring to FIG. 9, unlike the display device DD described in association with FIG. 8, in the display device DD_1, according to an embodiment, layers of the light controlling layer LCL_1 other than the filing layer FIL may be disposed on the upper substrate UPL and the filling layer FIL may be disposed between the upper capping layer CPL_Q of the light controlling layer LCL_1 and the display layer DL. In this manner, the filing layer FIL may be considered a part of the light controlling layer LCL_1 versus a part of the upper layer UL_1.

For example, components constituting the light controlling layer LCL_1 may be sequentially disposed on the upper substrate UPL. Accordingly, similar to as described in association with FIG. 8, the color filters CF may be disposed between the scattering layer SCL and the display layer DL (for example, the light emitting element LD of the display layer DL), and the scattering layer SCL may be disposed across two or more sub-pixel areas SPXA.

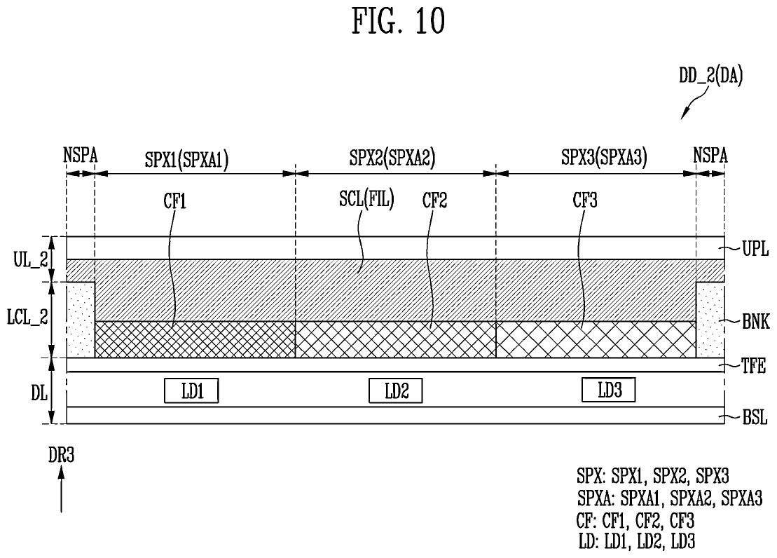

Referring to FIG. 10, unlike the display device DD described in association with FIG. 8, in the display device DD_2, according to an embodiment, the scattering layer SCL and the filling layer FIL may be manufactured integrally. For instance, the scattering layer SCL and the filling layer FIL may be integral with each other. In this manner, a first portion of the scatting and filing layer SCL(FIL) may form a part of the upper layer UL_2 and a second portion of the scattering and filing layer SCL(FIL) may form a part of the light controlling layer LCL_2.

For example, the scattering and filing layer SCL(FIL) may include scatterers and may include filling materials. Accordingly, the scattering and filing layer SCL(FIL) may perform the function of the filling layer FIL, and the scattering and filling layer SCL(FIL) may perform the function of the scattering layer SCL. Accordingly, manufacturing process steps can be simplified.

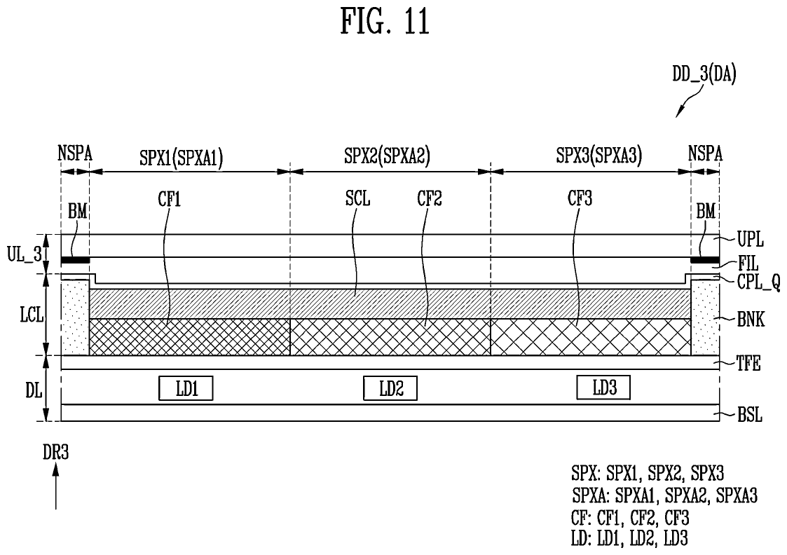

Referring to FIG. 11, unlike the display device DD described in association with FIG. 8, the display device DD_3, according to an embodiment, may further include a black matrix layer BM.

For example, the upper layer UL_3 may further include the black matrix layer BM disposed in the non-sub-pixel area NSPA. The black matrix layer BM may be disposed between the upper substrate UPL and the filling layer FIL. The black matrix layer BM may include a black matrix material (for example, carbon black and/or the like). The black matrix layer BM may be formed in the non-sub-pixel area NSPA so that the pixels PXL can be more clearly distinguished from each other, thereby improving visibility of the display device DD_3.

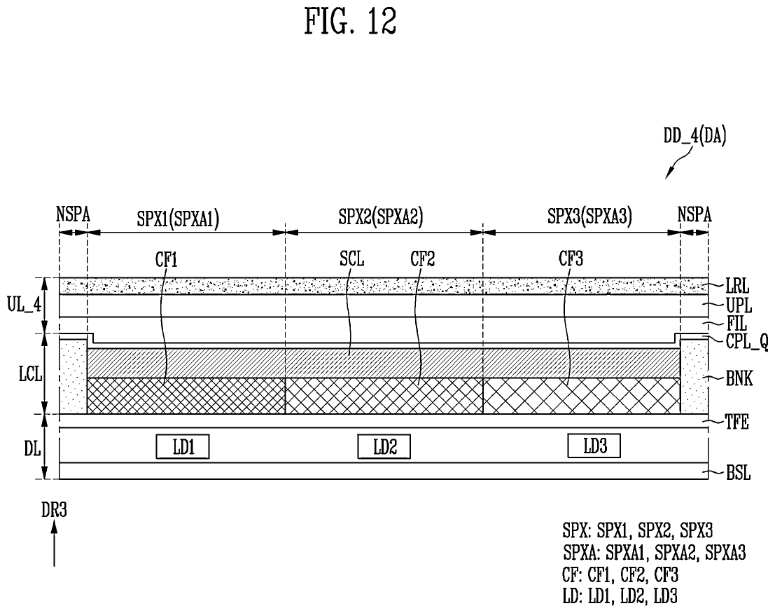

Referring to FIG. 12, unlike the display device DD described in association with FIG. 8, the display device DD_4, according to an embodiment, may further include a low-reflection layer LRL.

For example, the low-reflection layer LRL may be a functional layer formed as a portion of the upper layer UL_4 for reducing reflection of external light in and/or from the display device DD_4. For example, the low-reflection layer LRL may be an anti-reflection layer. The material of the low-reflection layer LRL is not limited to any particular material so long as the low-reflection layer LRL can function as an anti-reflection layer. Accordingly, the risk of reduced visibility due to reflection of external light in or from the display device DD_4 can be reduced by forming the low-reflection layer LRL.

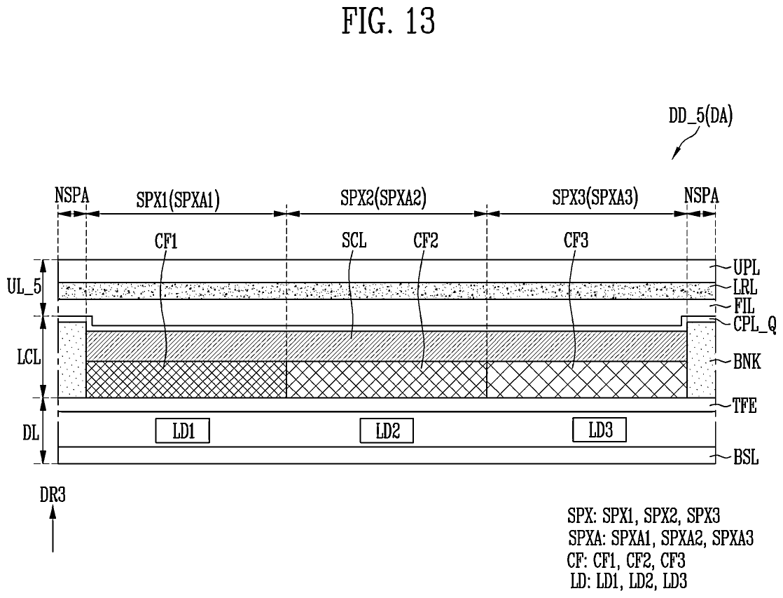

Referring to FIG. 13, unlike the display device DD_4 described in association with FIG. 12, in the display device DD_5, according to an embodiment, the low-reflection layer LRL may be disposed in the upper layer UL_5 below the upper substrate UPL.

For example, the low-reflection layer LRL may be disposed between the upper substrate UPL and the filling layer FIL. Accordingly, the risk of reduced visibility due to reflection of external light in or from the display device DD_5 can be reduced by forming the low-reflection layer LRL.

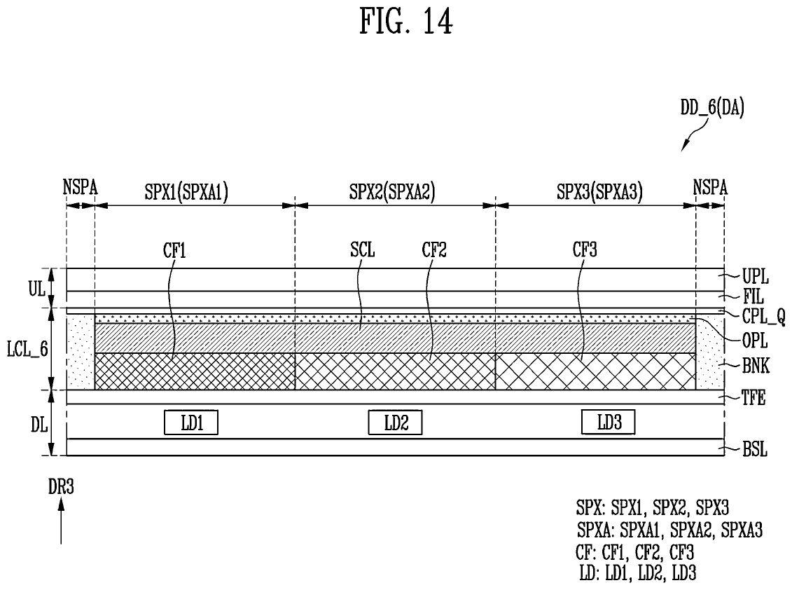

Referring to FIG. 14, unlike the display device DD described in association with FIG. 8, the display device DD_6, according to an embodiment, may further include an optical layer OPL formed in association with light controlling layer LCL_6.

For example, the optical layer OPL may be a relatively low refractive index layer. The optical layer OPL may have a lower refractive index than the scattering layer SCL. The optical layer OPL and the scattering layer SCL may form a light recycling structure. For instance, light propagating from the scattering layer SCL having an angle of incidence with the optical layer OPL greater than a critical angle may be reflected from the optical layer OPL and reintroduced into the scattering layer SCL where the light may then interact with scattering particles in the scattering layer SCL and made re-incident with the optical layer OPL. At some point, the re-incident light may propagate through the optical layer OPL and may be output from the display device DD_6. This may improve the light emitting efficiency of the display device DD_6. The optical layer OPL may include various materials and may have any suitable refractive index. For example, the optical layer OPL may include various resins and hollow silica. In some implementations, the optical layer OPL may include zirconium oxide (ZrOx), where “x” is a positive integer. However, embodiments are not limited to the above-noted materials. According to an embodiment, at least because the optical layer OPL may be formed as part of the display device DD_6, the light output efficiency and viewing angle characteristics of the display device DD_6 can be improved.

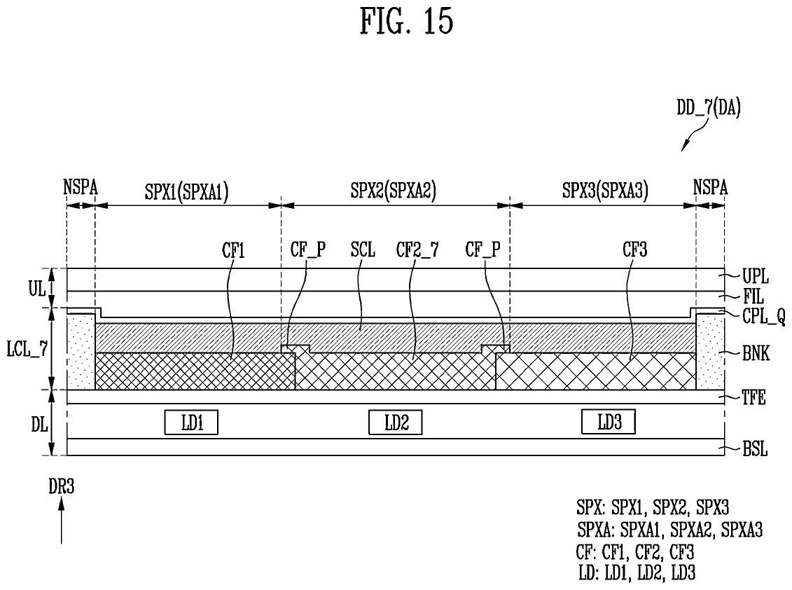

Referring to FIG. 15, unlike the display device DD described in association with FIG. 8, in the display device DD_7, according to an embodiment, at least some of the color filters CF of the light controlling layer LCL_7 may overlap each other in a plan view, e.g., at least some of the color filters CF may overlap each other in, for instance, the third direction DR3.

For example, a portion of at least one of the color filters CF may be disposed on another color filter among the color filters CF. For example, the second color filter CF2_7 may include protruding color filter parts CF_P, and the protruding color filter parts CF_P may overlap respective portions of the first color filter CF1 and the third color filter CF3 in a plan view, e.g., the protruding color filter parts CF_P of the second color filter CF2_7 may overlap respective portions of the first color filter CF1 and the third color filter CF3 in a, for instance, the third direction DR3.

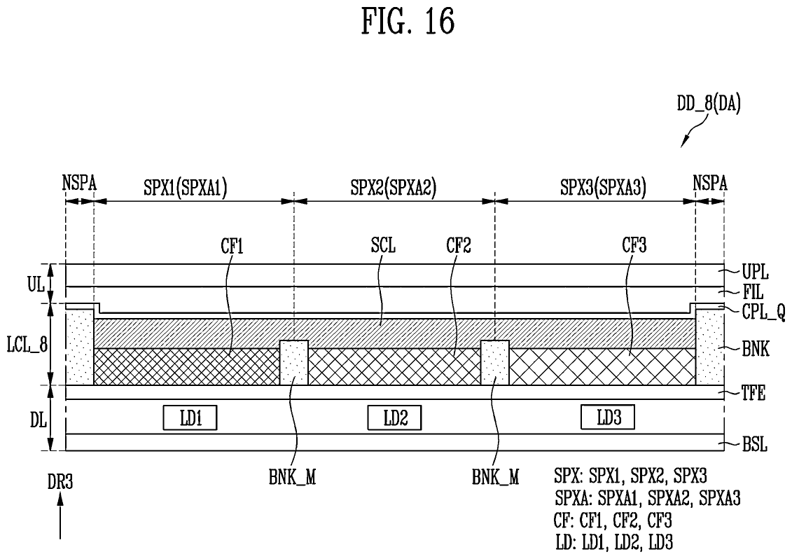

Referring to FIG. 16, unlike the display device DD described in association with FIG. 8, the display device DD_8, according to an embodiment, may further include an intermediate bank structure BNK_M form a portion of the light controlling layer LCL_8.

According to an embodiment, the intermediate bank structure BNK_M may be disposed between the color filters CF. The intermediate bank structure BNK_M may include a same material as the bank BNK and may protrude in the thickness direction of the base layer BSL (for example, in the third direction DR3). Accordingly, the intermediate bank structure BNK_M can further reduce the risk of color mixing between the color filters CF.

According to an embodiment, to reduce the risk of reducing an aperture ratio of the display device DD_8, the intermediate bank structure BNK_M may have a lower height in the third direction DR3 than the bank BNK. According to an embodiment, the intermediate bank structure BNK_M may have a thicker thickness (or height) than the color filter CF in the third direction DR3. Accordingly, the risk of color mixing can be further prevented (or at least mitigated) while also minimizing (or at least reducing) the reduction in the aperture ratio of the display device DD_8.

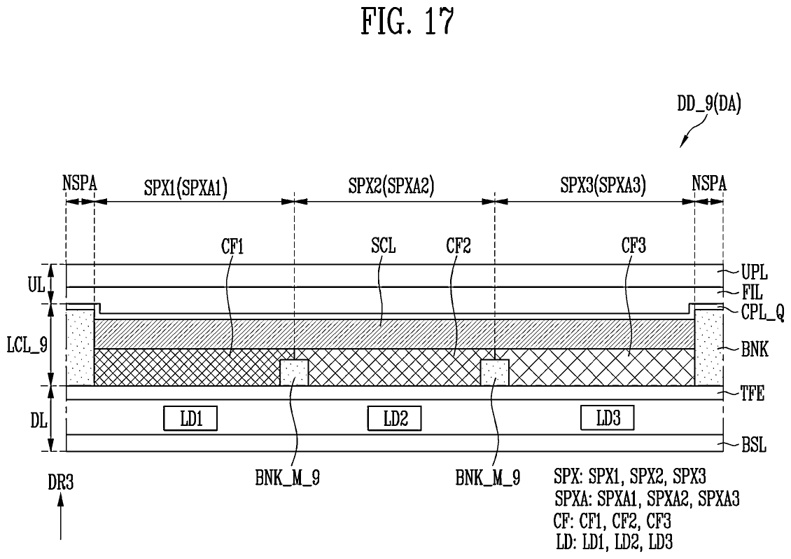

Referring to FIG. 17, unlike the display device DD_8 described in association with FIG. 16, in the display device DD_9, according to an embodiment, the intermediate bank structure BNK_M_9 of the light controlling layer LCL_9 may have a thickness (or height) in the third direction DR3 that is smaller than a corresponding thickness (or height) of the color filter CF in the third direction DR3.

For example, an upper surface of the intermediate bank structure BNK_M_9 may be covered (e.g., entirely covered) by the color filters CF. The risk of color mixing between the sub-pixels SPX can be reduced by the intermediate bank structure BNK_M_9, and the risk of reducing the aperture ratio of the display device DD_9 can also be prevented or at least mitigated.

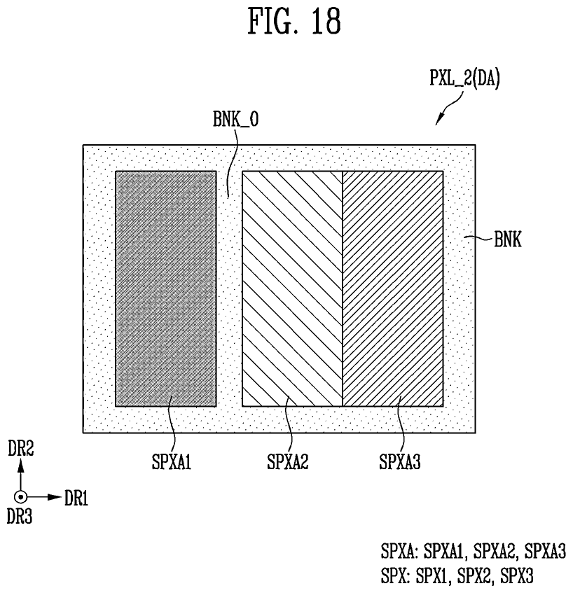

One or more display devices, according to various embodiments, will now be described with reference to FIGS. 18 to 27. Content that overlaps with the above-described content will be briefly explained or omitted.

The display devices shown in FIGS. 18 to 27 may be different from one or more of the previously described display devices in that one or more of the display devices described in association with FIGS. 18 to 27 may further include a color conversion layer CCL.

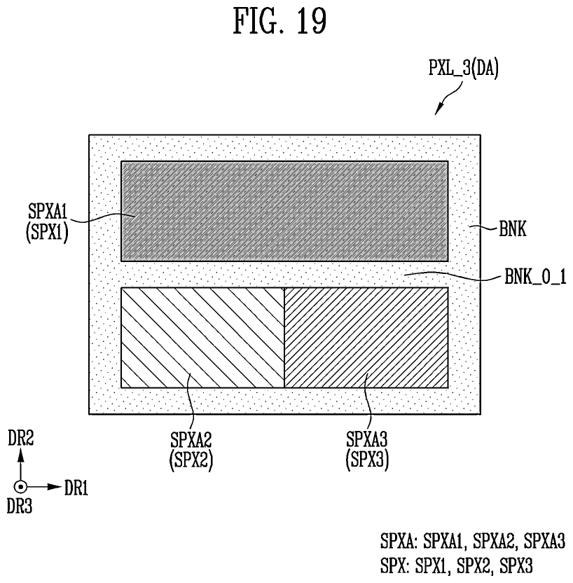

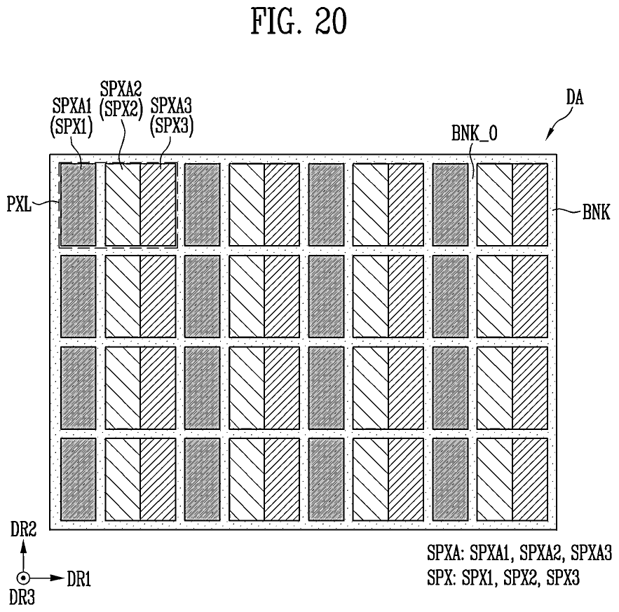

FIGS. 18 to 20 are plan views schematically illustrating one or more display devices according to some embodiments. FIGS. 18 and 19 show pixels PXL_2 and PXL_3 and schematically show arrangement structures of different sub-pixels SPX of pixels PXL_2 and PXL_3. FIG. 20 schematically shows an arrangement structure in which pixels PXL_2 are sequentially arranged in one or more directions, e.g., in both the first direction DR1 and the second direction DR2.

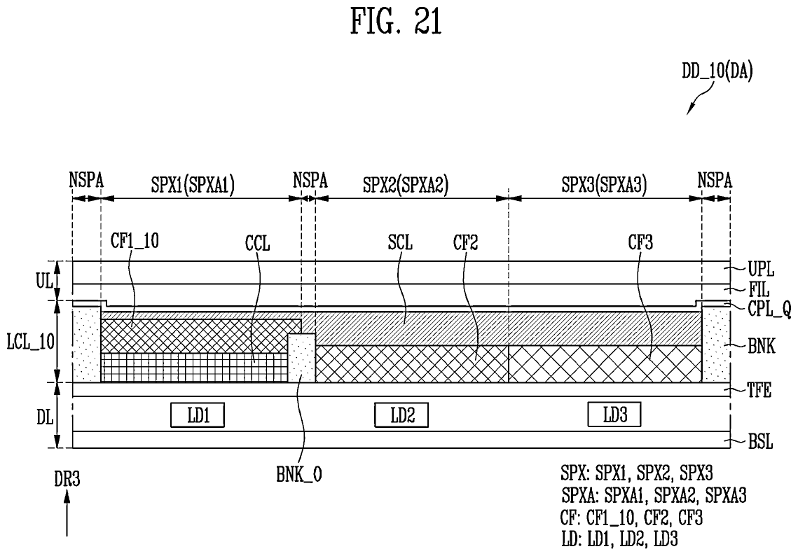

FIGS. 21 to 27 are cross-sectional views schematically illustrating one or more display devices according to some embodiments. FIGS. 21 to 27 schematically show the first to third sub-pixels SPX1 to SPX3 according to some embodiments.

Referring to FIGS. 18 to 20, a display device may further include an intermediate bank, such as intermediate bank BNK_O or BNK_O_1. For convenience, the intermediate banks BNK_O and BNK_O_1 will, hereinafter, be referred to as intermediate bank BNK_O, unless specific reference to a particular intermediate bank is made.

The intermediate bank BNK_O may be disposed between adjacent sub-pixel areas SPXA. For example, the intermediate bank BNK_O may be disposed between the first sub-pixel area SPXA1 and the second sub-pixel area SPXA2. As seen in FIG. 18, the intermediate bank BNK_O may longitudinally extend in the second direction DR2. The intermediate bank BNK_O_1 depicted in FIG. 19 may longitudinally extend in the first direction DR1. The intermediate bank BNK_O may be formed in a same process as the bank BNK and may include a same material as the bank BNK, but embodiments are not limited to such configurations.

The intermediate bank BNK_O may form an opening in association with bank BNK where the color conversion layer CCL is disposed. For example, the color conversion layer CCL may be disposed in the first sub-pixel area SPXA1. The intermediate bank BNK_O and the bank BNK may surround an area so that an area where the color conversion layer CCL is disposed is formed in the first sub-pixel area SPXA1, but embodiments are not limited to such configurations. For instance, the color conversion layer CCL may be additionally or alternatively disposed in association with at least one of the other sub-pixel areas SPXA.

Referring to FIG. 21, the display device DD_10 (e.g., the light controlling layer LCL_10 of display device DD_10) may further include the color conversion layer CCL disposed in the first sub-pixel area SPXA1.

The color conversion layer CCL may be disposed in the first sub-pixel area SPXA1 and may not be disposed in the second and third sub-pixel areas SPXA2 and SPXA3. However, embodiments are not limited to the aforementioned arrangement. For example, the color conversion layer CCL may be disposed in the first sub-pixel area SPXA1, and a color conversion layer including quantum dots may be disposed in the second sub-pixel area SPXA2. Hereinafter, for convenience of description, an embodiment in which the color conversion layer CCL is disposed only in the first sub-pixel area SPXA1 will be described as an example.

According to an embodiment, the intermediate bank BNK_O may be formed in the non-sub-pixel area NSPA between the first sub-pixel area SPXA1 and the second sub-pixel area SPXA2. The intermediate bank BNK_O may have a smaller thickness (for example, smaller height) than the bank BNK in, for instance, the third direction DR3.

The color conversion layer CCL may be disposed on the display layer DL (for example, the encapsulation layer TFE). The color conversion layer CCL may be disposed in an area surrounded by the bank BNK and the intermediate bank BNK_O. The color conversion layer CCL may overlap the first color filter CF1_10 in a plan view, e.g., in a direction perpendicular to the upper surface of the base layer BSL. The color conversion layer CCL may be disposed between the first color filter CF1_10 and the display layer DL. In some embodiments, a portion of the first color filter CF1_10 may overlap a corresponding portion of the color conversion layer CCL in, for example, the third direction DR3.

The color conversion layer CCL may be configured to change the color of light provided from the light emitting element LD. For example, the first light emitting element LD1 may emit light of the third color like the third light emitting element LD3, and the color conversion layer CCL may include color conversion particles that convert the light of the third color into light of the first color. For example, the color converting particles may be quantum-dots, but any other suitable color converting particles and/or materials may be utilized. The color conversion particles may absorb the light of the third color and shift the wavelength according to energy transition to emit the light of the first color. The color conversion particles can be prepared by dispersing them in a matrix layer made of an organic material or the like.

According to an embodiment, in a case that a layer similar to the color conversion layer CCL is formed in the second sub-pixel area SPXA2, the second light emitting element LD2 may emit light of the third color like the third light emitting element LD3, and the color conversion layer formed in the second sub-pixel area SPXA2 may include color conversion particles that convert the light of the third color into light of the second color. For example, the color conversion particles may absorb the light of the third color and shift the wavelength according to energy transition to emit the light of the second color. The color conversion particles can be prepared by dispersing them in a matrix layer made of an organic material or the like.

Similar to the embodiments described above, the scattering layer SCL may be disposed across the sub-pixel areas SPXA, and the above-described technical effects can be similarly provided or realized.

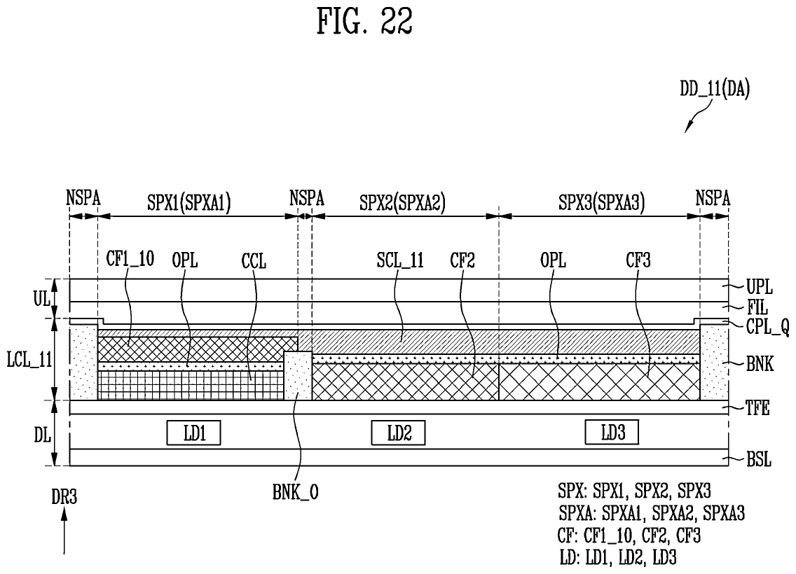

Referring to FIG. 22, unlike the display device DD_10 described in association with FIG. 21, the display device DD_11, according to an embodiment, may further include the optical layer OPL as part of the light controlling layer LCL_11.

According to an embodiment, the optical layer OPL may be disposed between the color conversion layer CCL and the first color filter CF1_0 in the first sub-pixel area SPXA1. The optical layer OPL may be disposed between the scattering layer SCL_11 and both the second color filter CF2 and the third color filter CF3.

The technical characteristics of the optical layer OPL have been previously described with reference to FIG. 14 and the like. For example, the optical layer OPL may form a light recycling structure. Accordingly, the light output efficiency and viewing angle characteristics of the display device DD_11 can be improved.

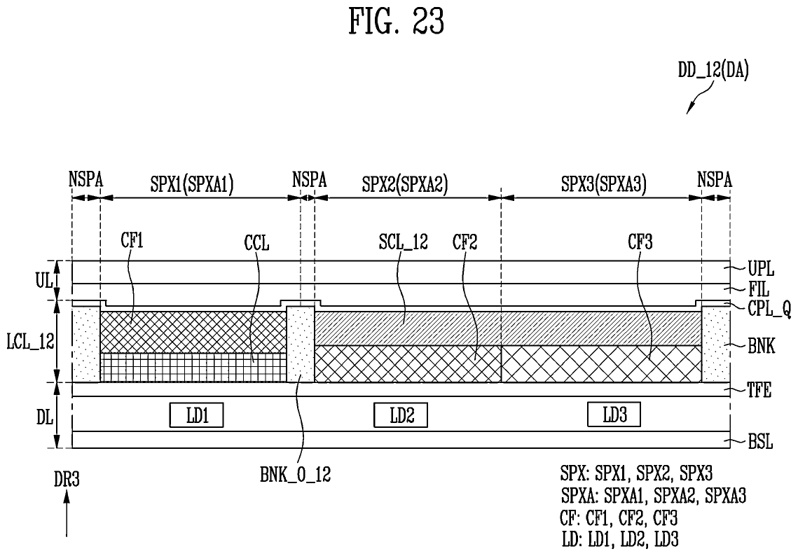

Referring to FIG. 23, unlike the display device DD_10 described in association with FIG. 21, in the display device DD_12, according to an embodiment, the scattering layer SCL_12 of the light controlling layer LCL_12 may not be disposed in the first sub-pixel area SPXA1, but may be disposed across the second and third sub-pixel areas SPXA2 and SPXA3.

For example, the scattering layer SCL_12 may include a first portion disposed in the second sub-pixel area SPXA2 and a second portion disposed in the third sub-pixel area SPXA3, and may not overlap the first sub-pixel area SPXA1 in a plan view, e.g. may not overlap the first sub-pixel area SPXA1 in the third direction DR3. Further, the first color filter CF1 may be protected by the upper capping layer CPL_Q. In some implementations, a thickness (or height) of the intermediate bank BNK_O_12 in the third direction DR3 may be greater than a corresponding thickness (or height) of the intermediate bank BNK_O described in association with at least FIG. 21. For instance, a thickness of the intermediate bank BNK_O_12 may be such that the first color filter CF1 does not overlap a portion of the intermediate bank BNK_O_12 in the third direction DR3 unlike as shown in FIG. 21 in which the first color filter CF1_10 overlaps a portion of intermediate bank BNK_O in the third direction DR3. In some cases, a portion of upper capping layer CPL_Q may be disposed on (e.g., disposed directly on) a portion (e.g., an upper surface) of the intermediate bank BNK_O_12.

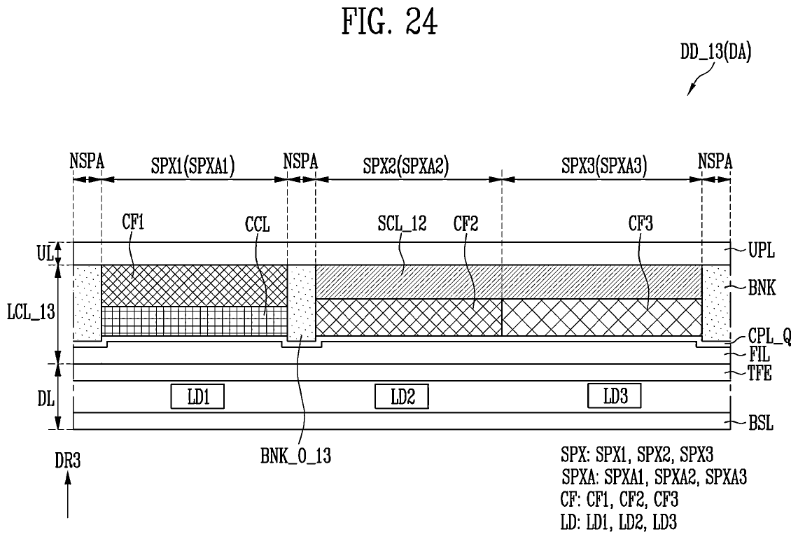

Referring to FIG. 24, unlike the display device DD_12 described in association with FIG. 23, in the display device DD_13, according to an embodiment, various layers of the light controlling layer LCL_13 may be disposed on the upper substrate UPL and both the upper capping layer CPL_Q and the filling layer FIL of the light controlling layer LCL_13 may be disposed between the color conversion layer CCL of the light controlling layer LCL_13 and the display layer DL.

For example, components constituting the light controlling layer LCL_13 may be sequentially disposed on the upper substrate UPL. Accordingly, similar to as previously described, the color filters CF may be disposed between the scattering layer SCL_12 and the display layer DL (for example, the light emitting element LD of the display layer DL), and the scattering layer SCL_12 may be disposed across two or more sub-pixel areas SPXA.

In some implementations, a surface (e.g., an upper surface) of the intermediate bank BNK_O_13 may be coplanar with a corresponding surface of at least one of the first color filter CF1 and the scattering layer SCL_12. As shown in FIG. 24, the upper surface of the intermediate bank BNK_O_13 is coplanar with corresponding surfaces of both the first color filter CF1 and the scattering layer SCL_12.

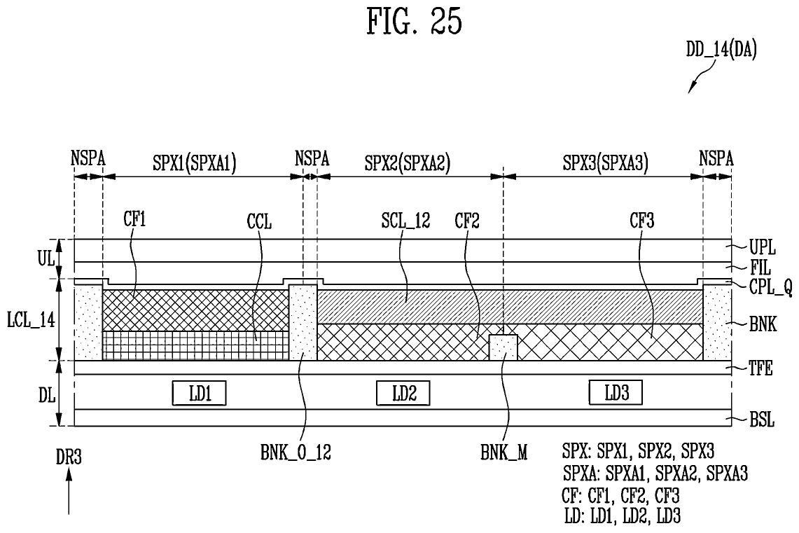

Referring to FIG. 25, unlike the display device DD_12 described in association with FIG. 23, the display device DD_14, according to an embodiment, may further include the intermediate bank structure BNK_M as part of the light controlling layer LCL_14.

According to an embodiment, the intermediate bank structure BNK_M may be disposed between the second color filter CF2 and the third color filter CF3 in, for instance, a direction transverse to the third direction DR3. Accordingly, the intermediate bank structure BNK_M can further reduce the risk of color mixing between the color filters CF.

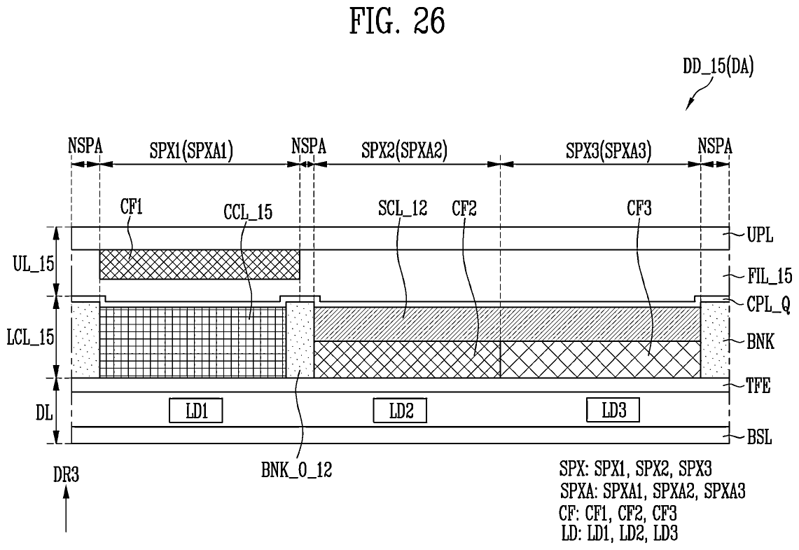

Referring to FIG. 26, unlike the display device DD_12 described in association with FIG. 23, in the display device DD_15, according to an embodiment, the first color filter CF1 may be disposed below the upper substrate UPL, such as disposed directly below the upper substrate UPL. In this manner, the first color filter CF1 may be formed as a portion of upper layer UL_15. Further, a thickness (or height) of the color conversion layer CCL_15 in the third direction DR3 may be greater than a corresponding thickness (or height) of the color conversion layer CCL. In some implementations, the thickness of the color conversion layer CCL_15 in the third direction DR3 may be less than the corresponding thickness of the intermediate bank BNK_O_12 in the third direction DR3.

For example, the first color filter CF1 may be manufactured by patterning it on the upper substrate UPL as part of the upper layer UL_15. Accordingly, the first color filter CF1 may be disposed between the upper substrate UPL and the filling layer FIL_15. Similar to as previously described, the sub-pixel areas SPXA may be defined by or in association with the color filters CF.

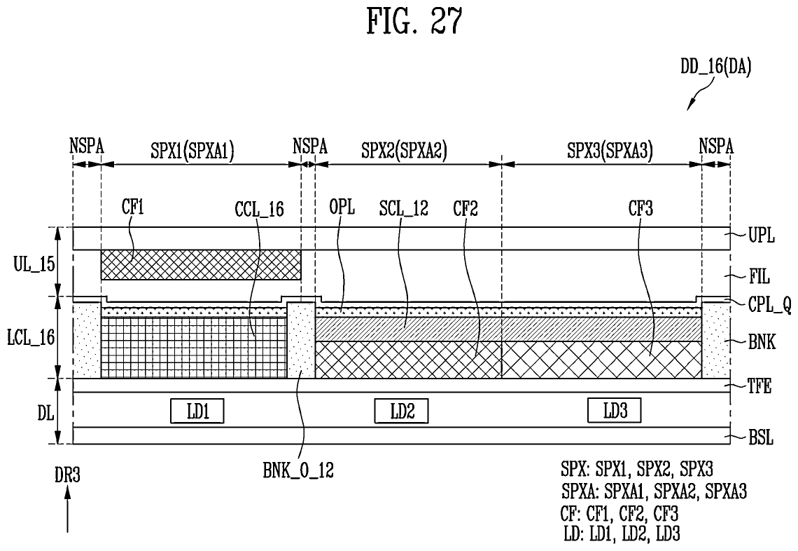

Referring to FIG. 27, unlike the display device DD_15 described in association with FIG. 26, the display device DD_16, according to an embodiment, may further include the optical layer OPL formed as part of the light controlling layer LCL_16.

According to an embodiment, the optical layer OPL may be disposed on the color conversion layer CCL_16, and the optical layer OPL may be disposed on the scattering layer SCL_12. In some cases, a thickness (or height) of the color conversion layer CCL_16 in the third direction DR3 may be smaller than a corresponding thickness (or height) of the color conversion layer CCL_15 in the third direction DR3, but greater than a corresponding thickness (or height) of the color conversion layer CCL in the third direction DR3. The technical characteristics of the optical layer OPL have been previously described with reference to FIG. 14 and the like. For example, the optical layer OPL may form a light recycling structure. Accordingly, the light output efficiency and viewing angle characteristics of the display device DD_16 can be improved.

According to some embodiments, a display device with relatively high-resolution display quality can be provided by improving an aperture ratio corresponding to an area where light is output.

According to some embodiments, a display device in which the risk of color mixing between sub-pixels is reduced can be provided.

According to some embodiments, a display device with improved convenience in process design for manufacturing a pixel can be provided.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A display device comprising:
a display layer; and
a light controlling layer disposed on a surface of the display layer, the light controlling layer comprising a color filter and a scattering layer,
wherein the color filter is disposed between the scattering layer and the display layer in a direction perpendicular to the surface of the display layer.

2. The display device of claim 1, further comprising:
a first sub-pixel configured to emit light of a first color;
a second sub-pixel configured to emit light of a second color; and
a third sub-pixel configured to emit light of a third color,
wherein the scattering layer respectively overlaps each of the first sub-pixel, the second sub-pixel, and the third sub-pixel in the direction.

3. The display device of claim 2, further comprising:
a bank surrounding an area in a view in the direction, wherein
each of the first sub-pixel, the second sub-pixel, and the third sub-pixel form respective sub-pixels of a pixel,
the display device comprises pixels and the pixel is one of the pixels,
the color filter comprises a first color filter overlapping the first sub-pixel in the direction, a second color filter overlapping the second sub-pixel in the direction, and a third color filter overlapping the third sub-pixel in the direction,
the pixels are spaced apart from one another by the bank, and
in a view in the direction:
an outer boundary of the first color filter corresponds with an outer boundary of the first sub-pixel;
an outer boundary of the second color filter corresponds with an outer boundary of the second sub-pixel; and
an outer boundary of the third color filter corresponds with an outer boundary of the third sub-pixel.

4. The display device of claim 3, wherein both the scattering layer and the color filter directly contact a side surface of the bank.

5. The display device of claim 3, wherein
the scattering layer comprises at least one of titanium oxide (TiOx), silica (SiOx), zirconium oxide (ZrOx), aluminum oxide (AlxOy), indium oxide (InxOy), zinc oxide (ZnOx), tin oxide (SnOx), and antimony oxide (SbxOy), where “x” and “y” are positive integers,
the silica optionally comprises at least one of silica beads and hollow silica,
the display layer comprises a light emitting element layer, and
the light emitting element layer comprises a first light emitting element layer configured to emit light of the first color, a second light emitting element layer configured to emit light of the second color, and a third light emitting element layer configured to emit light of the third color.

6. The display device of claim 2, further comprising:
a filling layer disposed on the scattering layer; and
an upper substrate disposed on the filling layer,
wherein, in the direction, the filing layer is disposed between the upper substrate and the display layer.

7. The display device of claim 2, further comprising:
a filling layer disposed between the color filter and the display layer in the direction; and
an upper substrate disposed on the scattering layer,
wherein, in the direction, the scattering layer is disposed between the upper substrate and the display layer.

8. The display device of claim 2, wherein the scattering layer comprises at least one filing material and scatterers dispersed in the at least one filling material.

9. The display device of claim 3, further comprising:
a non-sub-pixel area that does not overlap any of the first sub-pixel, the second sub-pixel, and the third sub-pixel in the direction; and
a black matrix layer,
wherein the bank and the black matrix layer are disposed in the non-sub-pixel area.

10. The display device of claim 6, further comprising:
a low-reflection layer disposed on the upper substrate,
wherein the upper substrate is disposed between the low-reflection layer and the display layer in the direction.

11. The display device of claim 6, further comprising:
a low-reflection layer disposed between the upper substrate and the filling layer in the direction.

12. The display device of claim 2, further comprising:
an optical layer overlapping each of the first sub-pixel, the second sub-pixel, and the third sub-pixel in the direction,
wherein a refractive index of the optical layer is lower than a refractive index of the scattering layer.

13. The display device of claim 3, further comprising:
an intermediate bank structure disposed between at least two of the first sub-pixel, the second sub-pixel, and the third sub-pixel in a view in the direction,
wherein a height of the intermediate bank structure from the surface of the display layer in the direction is smaller than a height of the bank from the surface of the display layer in the direction.

14. The display device of claim 13, wherein
the intermediate bank structure comprises a first surface facing the display layer and a second surface opposing the first surface, and
the second surface of the intermediate bank structure is covered by the color filter.

15. The display device of claim 3, further comprising:
a color conversion layer disposed between the first color filter and the display layer in the direction; and
an intermediate bank surrounding at least a portion of the color conversion layer in a view in the direction.

16. The display device of claim 15, further comprising:
an optical layer disposed on the color filter, the optical layer having a refractive index that is smaller than a refractive index of the scattering layer,
wherein, in the direction, a portion of the optical layer is disposed between the first color filter and the color conversion layer in an area overlapping the first sub-pixel in the direction.

17. The display device of claim 1, further comprising:
a first sub-pixel configured to emit light of a first color;
a second sub-pixel configured to emit light of a second color;
a third sub-pixel area configured to emit light of a third color; and
a color conversion layer overlapping the first sub-pixel in the direction, wherein
the color filter comprises a first color filter overlapping the first sub-pixel in the direction, a second color filter overlapping the second sub-pixel in the direction, and a third color filter overlapping the third sub-pixel in the direction,
the color conversion layer is disposed between the first color filter and the display layer in the direction,
the scattering layer does not overlap the first sub-pixel in the direction, and
the scattering layer respectively overlaps both the second sub-pixel and the third sub-pixel in the direction.

18. The display device of claim 17, further comprising:
an intermediate bank structure disposed between the second sub-pixel and the third sub-pixel in a view in the direction,
wherein a height of the intermediate bank structure from the surface of the display layer in the direction is smaller than a height of the bank from the surface of the display layer in the direction.

19. The display device of claim 17, further comprising:
an upper layer disposed on the light controlling layer, the upper layer comprising a filling layer and an upper substrate on the filling layer, wherein
the filing layer is disposed between the upper substrate and the display layer in the direction, and
the first color filter is disposed between the upper substrate and the filling layer in the direction.

20. The display device of claim 19, further comprising:
an optical layer, wherein
at least a first portion of the optical layer is disposed on the color conversion layer,
at least a second portion of the optical layer is disposed on the scattering layer, and
a refractive index of the optical layer is smaller than a refractive index of the scattering layer.
